(19) United States
(12) Patent Application Publication
(10) Pub. No.: US 2009/0302874 A1
(43) Pub. Date: Dec. 10, 2009

(54) METHOD AND APPARATUS FOR SIGNAL PROBE CONTACT WITH CIRCUIT BOARD VIAS

(75) Inventors: Paul M. Harvey, Austin, TX (US); Samuel W. Yang, Austin, TX (US); Yaping Zhou, Austin, TX (US)

Correspondence Address: IBM-ACC-Washington;c/o Myers Andras Sherman LLP, 19900 MacArthur Blvd., Suite 1150, Irvine, CA, 92612, US

(73) Assignee: International Business Machines Corporation, Armonk, NY (US)

(21) Appl. No.: 12/135,119

(22) Filed: Jun. 6, 2008

(51) Int. Cl. G01R 1/067

(52) U.S. Cl. 324/757

(57) ABSTRACT

A method and apparatus for probing a circuit board, is provided. One implementation involves a signal probe including a tip having a plurality of strands of flexible conductive material surrounding the tip, the strands extending out from the tip to provide multiple points of contact with the rim of a via or a conductive barrel of the via when the tip is inserted into the via, the probe tip and probe strands being made of same conductive material; such that aligning the signal probe with the via for engaging the probe tip strands with the via, and inserting the tip into the via, causes bending and flexing of the strands for making contact with a conductor on a top rim of the barrel and inside an inner wall of the barrel.

### BACKGROUND OF THE INVENTION

1. Field of the Invention

The present invention relates generally to probing circuit boards and, in particular, to signal probes for probing circuit boards.

2. Description of the Related Art

Signal probes are used for oscilloscopes, logic analyzers, and other test equipment for probing printed circuit boards. Vias are typically placed on the front or back side of a printed circuit board to which traces are connected. Conventional through vias (non-buried, non-blind) go through the entire circuit board (PCB). Referring to FIG. 1, to measure a signal, the opening of the via on the front or back side of the board is probed with browser probes. A typical browser probe includes an electrically conductive tip that is maneuvering from one measuring spot to another, for measuring signals.

However, existing signal probes are unreliable in providing an electrical connection at possible points of contact on a via. Even with pressure applied in a downward motion onto the via, the connection between the tip and the copper of the barrel of the via is not guaranteed. Probe tips are standardized and have one sharp point. Depending on the size of the via, probing a via with conventional probes can be difficult as there are not many possible points of contact where the probe tip can hit the via conductor. When a conventional probe tip is on the rim of the barrel of the via, the probe tip easily slips off and the point of contact (POC) is lost. When such a probe tip is placed inside the barrel of the via, although the tip may be submerged in the barrel, there is no guarantee that the tip is actually touching the copper inside the via (the via hole diameter may be much larger than the diameter of the probe tip, therefore, no connection is made).

### BRIEF SUMMARY OF THE INVENTION

The invention provides a method and apparatus for probing a circuit board. One embodiment involves a signal probe head including a tip having a plurality of strands of flexible conductive material surrounding the tip, the strands extending out from the tip to provide multiple points of contact with a conductive barrel of the via when the tip is inserted into the via, the probe tip and probe strands being made of same conductive material; such that aligning the signal probe with the via for engaging the probe tip strands with the via, and inserting the tip into the via, causes bending and flexing of the strands for making contact with a conductor on a top rim of the barrel and inside an inner wall of the barrel.

Other aspects and advantages of the present invention will become apparent from the following detailed description which, when taken in conjunction with the drawings, illustrate, by way of example, the principles of the invention.

### BRIEF DESCRIPTION OF THE DRAWINGS

For a fuller understanding of the nature and advantages of the invention, as well as a preferred mode of use, reference should be made to the following detailed description read in conjunction with the accompanying drawings, in which:

FIG. 1 shows a conventional signal probe for probing a via on a circuit board.

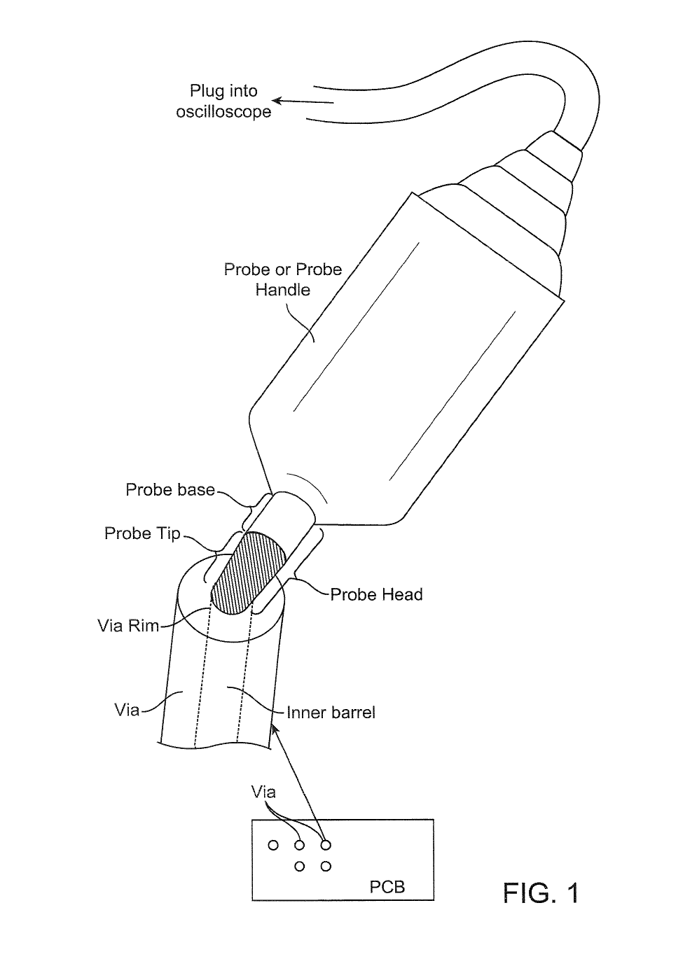

FIG. 2 shows an embodiment of a probe head for a signal probe, according to the invention.

FIG. 3 shows an embodiment of a detachable probe head for a signal probe, according to the invention.

FIG. 4 shows an example method of probing a via of a circuit board, according to an embodiment of the invention.

Other aspects and advantages of the present invention will become apparent from the following detailed description which, when taken in conjunction with the drawings, illustrate, by way of example, the principles of the invention.

### DETAILED DESCRIPTION OF THE PREFERRED EMBODIMENTS

The following description is made for the purpose of illustrating the general principles of the invention and is not meant to limit the inventive concepts claimed herein. Further, particular features described herein can be used in combination with other described features in each of the various possible combinations and permutations. Unless otherwise specifically defined herein, all terms are to be given their broadest possible interpretation including meanings implied from the specification as well as meanings understood by those skilled in the art and/or as defined in dictionaries, treatises, etc.

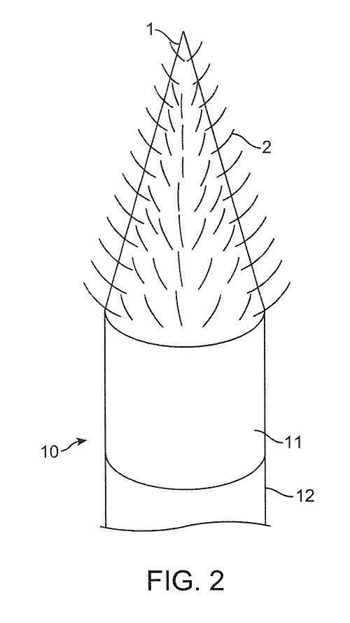

The invention provides a method and apparatus for probing a circuit board. Referring to FIG. 2, one embodiment comprises a signal probe head apparatus 10 having a base 11 and tip 1. The base 11 is attached to the handle 12 of the probe. The tip 1 has strands 2 of flexible conductive material surrounding the tip, the strands extending out from the tip to provide multiple points of contact with the barrel of a via when the tip is inserted into the via. Engaging the probe tip strands with the via, as the probe is inserted into the via, the strands bend and flex causing the strands to make contact with conductor on a top rim of the barrel and/or inside an inner wall of the barrel. Preferably, the probe tip 1 and probe strands 2 are made of same conductive material (e.g., beryllium copper), thus preserving quality electrical conductivity. In other words, tip strands are made of the same conductive material as the tip of the probe head.

The invention improves the browser probe connection when the probe tip makes contact with a via by providing many POC through the multiple strands 2. The tip can be made to a desired diameter to fit multiple industry standard via barrels.

The strands 2 fan out of the tip 1 at an upward angle. As a result, as the tip goes into the barrel of the via, the strands bend outward and help contact the copper better. The purpose being, when the tip is inserted into a via, the strands will have a higher probability of catching the sides of the barrel, thus making a good POC. Each strand is a possible POC, thus increasing the chance of a connection by as many strands there are on a probe tip.

Different types of probe tips can be made with different base diameters, different lengths and different number of strands (a few sized probe tips provide variety for different size vias).

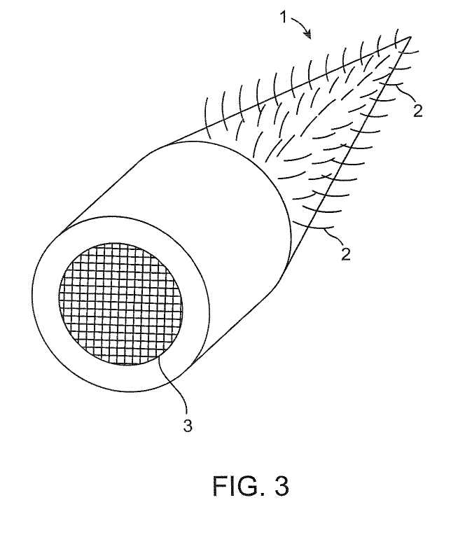

FIG. 3 shows another example of a signal probe tip 1 according to the invention, wherein the probe tip is detachable through a conductive portion 3 of the base 11 (the entire base 11 may be conductive). When the probe tip 1 is attached on to the handle 12 of the probe, the signal path is through the conductive portion 3 on the base 11 of the probe tip 1.

The entire probe head 10 can be detached from the handle 12 of the main browser probe (FIG. 2). This enables the user to pick different probe tips in order to fit the specific via on the DUT (device under test).

A method of probing vias on a circuit board according to the invention involves aligning a signal probe head with at least a via on a printed circuit board, wherein the signal probe head includes a tip having a plurality of strands of flexible conductive material surrounding the tip, the strands extending out from the tip to provide multiple points of contact with a barrel of the via when the tip is inserted into the via, the probe tip and probe strands being made of same conductive material; and engaging the probe tip strands with the via, such that as the probe tip is inserted into the via, the strands bend and flex causing the strands to make contact with the conductor on the top rim of the barrel and inside the inner wall of the barrel.

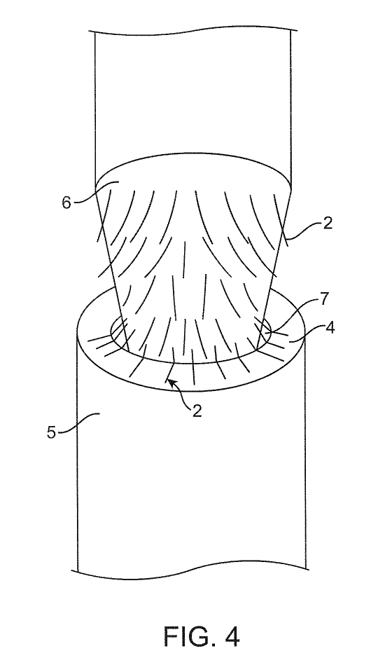

FIG. 4 illustrates that a probe tip 6 with multiple strands 2, according to the invention, is inserted down the barrel 7 of a via 5, the probe strands 2 bend and flex on a rim 4 of the barrel 7 of the via 5, causing said strands 2 to make contact with the copper on the top rim 4 of the via and inside the inner wall of the barrel of the via 5. Because the probe tip 6 can be changed and picked for any given via size, there is a higher probability of multiple POC as the strands 2 flex on a rim 4 on top and inside the via 5.

In another example, shorter strands with thicker diameter probe tips can be used. This provides another POC approach wherein with shorter strands and a thicker diameter tip, the strands flex and bend less than the examples above. The POC is not primarily on the top rim of the via, but more on the inside of the barrel. The stronger/shorter strands will be able to scratch the inside of the via as it is pushed down the barrel, making good electrical contacts. Scratching the copper of the barrel guarantees a solid connection.

As such, embodiments of the invention provide a probe tip allowing probing a single signal via (a fine point) with a single probe tip with multiple points of contact through strands on the tip. This provides ability to probe a single via, and improves contact with a via through the strands. A single tip with many points of contact (conductive strands) on the same tip, allow signal measurement for probing a signal.

Those skilled in the art will appreciate that various adaptations and modifications of the just-described preferred embodiments can be configured without departing from the scope and spirit of the invention. Therefore, it is to be understood that, within the scope of the appended claims, the invention may be practiced other than as specifically described herein.

1. A signal probe apparatus for probing a via on a printed circuit board, comprising:
a signal probe including a cone shaped tip to accommodate different sized vias wherein the cone shaped tip can be inserted in different size vias, even when the vias are smaller than the diameter at the base of the tip cone, the tip having a plurality of strands of flexible conductive material surrounding the tip, the strands extending out from the tip to provide multiple points of contact with the rim and the inner wall of a conductive barrel of a via when at least a portion of the tip is inserted into the via, the probe tip and probe strands being made of same conductive material;
such that aligning the signal probe with the via for engaging the probe tip strands with the via, and inserting at least a portion of the tip into the via, causes bending and flexing of the strands for making contact with a conductor on a top rim of the barrel and inside the inner wall of the barrel.
